(19) United States
(12) Patent Application Publication
(10) Pub. No.: US 2026/0008957 A1
(43) Pub. Date: Jan. 8, 2026

(54) ETCHING COMPOSITION, METHOD FOR MANUFACTURING ETCHING COMPOSITION, ETCHING METHOD, METHOD FOR MANUFACTURING SEMICONDUCTOR DEVICE, AND METHOD FOR MANUFACTURING GATE-ALL-AROUND TRANSISTOR

(71) Applicant: MITSUBISHI CHEMICAL CORPORATION, Tokyo (JP)

(72) Inventors: Tetsuo KASAI, Tokyo (JP); Hiroyuki SHIRAE, Tokyo (JP)

(73) Assignee: MITSUBISHI CHEMICAL CORPORATION, Tokyo (JP)

(21) Appl. No.: 19/325,340

(22) Filed: Sep. 10, 2025

Related U.S. Application Data
(63) Continuation of application No. PCT/JP2024/008999, filed on Mar. 8, 2024.

(30) Foreign Application Priority Data
Mar. 14, 2023 (JP) 2023-040024

(51) Int. Cl. C09K 13/00; H01L 21/306; H10D 30/01

(52) U.S. Cl. CPC C09K 13/00; H01L 21/30604; H10D 30/0191

(57) ABSTRACT

An etching composition containing a semiclathrate hydrate-forming compound (A), wherein the compound (A) comprises a compound having a melting point of 5° C. or higher when the compound (A) is made into an aqueous solution having a concentration of 1 mol/L, the etching composition has an oxygen concentration of 2 ppm by mass or less, and the etching composition has a mass ratio of oxygen to the compound (A) of from 1×10⁻⁸ to 1×10⁻⁴.

### CROSS-REFERENCE TO RELATED APPLICATIONS

The present application is a continuation of International Patent Application PCT/JP2024/008999, filed Mar. 8, 2024, which is based on and claims the benefit of priority to Japanese Patent Application No. 2023-040024 filed on Mar. 14, 2023. The entire contents of these applications are incorporated herein by reference.

### TECHNICAL FIELD

The present disclosure relates to an etching composition, a method for manufacturing an etching composition, an etching method, a method for manufacturing a semiconductor device, and a gate-all-around transistor.

### BACKGROUND ART

Integrated circuits have become miniaturized in accordance with Moore's law.

In recent years, studies have been conducted not only to reduce the size of a known planar transistor but also to improve the performance of a transistor by changing its structure from a planar structure to a three-dimensional structure, as is the case for a Fin transistor (Fin FET) or a gate-all-around transistor (GAA FET), and to further miniaturize and integrate the transistor.

In the Fin FET, by forming a Fin in a direction perpendicular to a silicon substrate to form a multi-gate device, not only the number of transistors per unit area can be increased, but also an off-state leakage current can be suppressed. Therefore, the effect of an on-state current is also improved, and thus low power consumption and low heat generation are achieved.

In order to further improve the performance, it is necessary to increase an aspect ratio of the Fin. However, too large an aspect ratio of the Fin causes some issues, for example, the Fin collapses in a cleaning step or a drying step for forming the Fin.

In the GAA FET, a nanosheet or nanowire-shaped channel is covered with a gate electrode to increase a contact area between a channel and a gate electrode, thereby improving the performance of the transistor per unit area.

In order to form the GAA FET, it is necessary to have an etching liquid for selectively etching silicon or silicon germanium from a structure in which silicon and silicon germanium are alternately stacked.

As such an etching liquid, Patent Document 1 discloses an etching liquid containing a quaternary ammonium salt.

### CITATION LIST

### Patent Literature

Patent Document 1: WO 2022/153658

### SUMMARY

### Technical Problem

In Patent Document 1, an oxygen concentration in an etching composition is not studied. In the etching composition of Patent Document 1, when the oxygen concentration is high, selective solubility of silicon relative to silicon germanium cannot be said to be sufficient.

In particular, in recent years, there has been a strong demand for miniaturization of an FET, and an etching liquid for selectively etching silicon or silicon germanium in a narrow gap of several tens of nanometers is required. Such a narrow gap results in an extremely lower etch rate than that when a smooth substrate is etched. In addition, the selective solubility in the narrow gap may be different from that in a smooth substrate. Therefore, an etching liquid suitable for etching such a narrow gap is required.

The performance of a semiconductor is also affected by a difference in structure of several nanometers after etching and surface conditions of a substrate after etching. Silicon has etching anisotropy, and the surface after etching may not be smooth. Therefore, etching is required to smooth the surface of the substrate after etching.

The present disclosure has been made in view of such issues.

An object of the present disclosure is to provide an etching composition, which suppresses dissolution of silicon germanium, promotes dissolution of silicon, has excellent selective solubility of silicon relative to silicon germanium, and provides an excellent surface state of a substrate after etching, and a method for manufacturing the etching composition.

Another object of the present disclosure is to provide an etching method, a method for manufacturing a semiconductor device, and a method for manufacturing a gate-all-around transistor, using the etching composition.

### Solution to Problem

The present inventor has found that an etching composition described below and an etching composition produced by a method for manufacturing an etching composition described below suppress dissolution of silicon germanium, promote dissolution of silicon, have excellent selective solubility of silicon relative to silicon germanium, and provide an excellent surface state of a substrate after etching.

Specifically, the gist of the present disclosure is as follows.
[1] An etching composition containing a semiclathrate hydrate-forming compound (A), wherein the semiclathrate hydrate-forming compound (A) is a compound having a melting point of 5° C. or higher when the semiclathrate hydrate-forming compound (A) is made into an aqueous solution having a concentration of 1 mol/L, and the etching composition has an oxygen concentration of 2 ppm by mass or less, and a mass ratio of oxygen to the semiclathrate hydrate-forming compound (A) of from 1×10⁻⁸ to 1×10⁻⁴.
[2] The etching composition according to [1], wherein the semiclathrate hydrate-forming compound (A) includes an onium compound.
[3] The etching composition according to [2], wherein the semiclathrate hydrate-forming compound (A) includes at least one selected from the group consisting of an ammonium salt compound and a phosphonium salt compound.
[4] The etching composition according to any one of [1] to [3], wherein the semiclathrate hydrate-forming compound (A) includes a compound having 10 or more carbon atoms.
[5] The etching composition according to any one of [2] to [4], wherein the semiclathrate hydrate-forming compound (A) includes an onium compound having four identical substituents.
[6] The etching composition according to any one of [1] to [5], wherein a concentration of the semiclathrate hydrate-forming compound (A) in the etching composition is from 0.01 mol/L to 3 mol/L.
[7] An etching composition containing a quaternary ammonium halide, wherein the etching composition has an oxygen concentration of 2 ppm by mass or less.
[8] An etching composition containing a phosphonium salt compound, wherein the etching composition has an oxygen concentration of 2 ppm by mass or less.
[9] The etching composition according to any one of [1] to [8], further containing a basic compound (B).
[10] The etching composition according to [9], wherein a concentration of the basic compound (B) in the etching composition is from 0.01 mol/L to 3 mol/L.
[11] The etching composition according to any one of [1] to [10], further containing water.
[12] The etching composition according to any one of [1] to [11], wherein the etching composition has a pH of from 8 to 14.
[13] The etching composition according to any one of [1] to [12], wherein the etching composition selectively dissolves silicon relative to silicon germanium.
[14] A method for manufacturing an etching composition, the method including bubbling a gas having an oxygen concentration of 8 vol % or less in an etching composition containing a semiclathrate hydrate-forming compound (A).
[15] An etching method including etching a structure containing silicon and silicon germanium using the etching composition described in any one of [1] to [13].
[16] A method for manufacturing a semiconductor device, the method including etching a structure containing silicon and silicon germanium using the etching composition described in any one of [1] to [13].
[17] A method for manufacturing a gate-all-around transistor, the method including etching a structure containing silicon and silicon germanium using the etching composition described in any one of [1] to [13].

### Advantageous Effects

The etching composition of the present disclosure suppresses dissolution of silicon germanium, promotes dissolution of silicon, has excellent selective solubility of silicon relative to silicon germanium, and provides an excellent surface state of a substrate after etching.

In addition, an etching composition produced by the method for manufacturing an etching composition of the present disclosure suppresses dissolution of silicon germanium, promotes dissolution of silicon, has excellent selective solubility of silicon relative to silicon germanium, and has an excellent surface state of a substrate after etching.

The etching method of the present disclosure, the method for manufacturing a semiconductor device of the present disclosure, and the method for manufacturing a gate-all-around transistor of the present disclosure using the etching composition of the present disclosure can suppress dissolution of silicon germanium, promote dissolution of silicon, and perform etching with high accuracy due to excellent selective solubility of silicon relative to silicon germanium in the etching step, thereby manufacturing a desired product having an excellent surface state with a high yield.

### DESCRIPTION OF EMBODIMENTS

Hereinafter, embodiments of the present disclosure will be described in detail. Hereinafter, the present disclosure is not limited to the following embodiments and can be carried out with various modifications within the scope of the gist thereof.

In the present specification, a numerical range expressed by using the term “to” means that the numerical values or physical property values before and after “to” are included in the numerical range.

### [Etching Composition]

An etching composition according to a first embodiment of the present disclosure contains a semiclathrate hydrate-forming compound (A), the compound (A) is a compound having a melting point of 5° C. or higher when the compound (A) is made into an aqueous solution having a concentration of 1 mol/L, and the etching composition has an oxygen concentration of 2 ppm by mass or less, and a mass ratio of oxygen to the compound (A) of from 1×10⁻⁸ to 1×10⁻⁴.

An etching composition according to a second embodiment of the present disclosure contains a quaternary ammonium halide and has an oxygen concentration of 2 ppm by mass or less.

An etching composition according to a third embodiment of the present disclosure contains a phosphonium salt compound and has an oxygen concentration of 2 ppm by mass or less.

Hereinafter, the etching composition according to the first embodiment of the present disclosure is sometimes referred to as “etching composition (1) of the present disclosure,” the etching composition according to the second embodiment of the present disclosure is sometimes referred to as “etching composition (2) of the present disclosure,” and the etching composition according to the third embodiment of the present disclosure is sometimes referred to as “etching composition (3) of the present disclosure”.

The etching compositions (1) to (3) of the present disclosure are sometimes collectively referred to as “the etching composition of the present disclosure.”

### (Mechanism)

A dissolution reaction of silicon involves hydroxide ions and water. Therefore, a state of molecules serving as a reaction attacking species is considered to be an important factor in control of a reaction.

Semiclathrate hydrate (clathrate hydrate) is known as a special crystal formed by molecules called guest molecules being enclosed inside a cage-like structure formed by water molecules through hydrogen bonding (Amid, M., et al., J Incl Phenom Macrocycl Chem 100, 109-129 (2021)). In the present specification, the semiclathrate hydrate is defined as a substance in which water molecules form a cage-like crystal structure with molecules other than water molecules called guest molecules as a part of the structure. The semiclathrate hydrate-forming compound is defined as a molecule, other than water, capable of forming a semiclathrate hydrate, the molecule called a guest molecule. In the semiclathrate hydrate, a phase change temperature can be controlled by selecting the guest molecule, whereby a melting point of the crystal of the semiclathrate hydrate can be changed. After the semiclathrate hydrate is molten, it is no longer in a crystalline state, but a hydrated state in a solution is closely related to a hydrated structure in a crystal. That is, it is likely that a special hydrated state that is involved in formation of a special crystal, called a semiclathrate hydrate, is formed. The reaction by the water molecules forming the special hydrated structure suppresses dissolution of silicon germanium and promotes dissolution of silicon. As a result, excellent selective solubility of silicon relative to silicon germanium and an excellent surface state of a substrate after etching can be obtained.

In addition, the etch rate of silicon germanium increases due to the presence of oxygen, and the selective solubility of silicon relative to silicon germanium decreases. Diffusion of oxygen is remarkably restricted by the hydrated structure after the semiclathrate hydrate is molten, and the selective solubility of silicon relative to silicon germanium is remarkably improved by setting the oxygen concentration to 2 ppm by mass or less. This makes it possible to improve the surface state of the substrate after etching.

### (Component (A))

The etching composition (1) of the present disclosure contains a semiclathrate hydrate-forming compound (A) (hereinafter, sometimes referred to as “component (A)”).

The semiclathrate hydrate-forming compound is a molecule, other than water, capable of forming a semiclathrate hydrate as described above. Preferably, the compound serves as a guest molecule that stabilizes the clathrate hydrate by participating in a hydrogen bonding network. A compound having a melting point of 5° C. or higher when made into an aqueous solution having a concentration of 1 mol/L is used as the component (A) since the reactivity of water molecules is excellently controlled by hydration in a temperature range where the etch rate is high. The component (A) is preferably a compound having a melting point of from 10° C. to 40° C. when made into an aqueous solution having a concentration of 1 mol/L, because the reactivity of water molecules is more excellently controlled.

The melting point can be measured by a differential scanning calorimeter (DSC). It can be confirmed that a compound has a melting point of 5° C. or higher by, for example, observing at least one endothermic peak having a peak top of 5° C. or higher when the compound is made into an aqueous solution having a concentration of 1 mol/L and the aqueous solution is heated at a temperature rising rate of 10° C./min or less by DSC.

The etching composition (1) of the present disclosure contains the component (A) and thus suppresses dissolution of silicon germanium, promotes dissolution of silicon, has excellent selective solubility of silicon relative to silicon germanium, and provides an excellent surface state of a substrate after etching.

Examples of the component (A) include onium compounds such as ammonium salts and phosphonium salts.

The onium compound is a substance generated by protonation of a hydride, and a representative example thereof is ammonium hydroxide.

One of these components (A) may be used alone, or two or more thereof may be used in combination.

Among these components (A), a derivative produced by substituting a hydrogen atom with an atomic group of a single bond is preferable; a derivative produced by substituting a hydrogen atom with an alkyl group of a single bond is more preferable; an ammonium salt compound and a phosphonium salt compound are still more preferable; and an alkylammonium salt compound and an alkylphosphonium salt compound are particularly preferable, because of excellent stability.

The component (A) is preferably a compound having 10 or more carbon atoms, more preferably a compound having from 14 to 32 carbon atoms, and still more preferably a compound having from 16 to 24 carbon atoms, because the semiclathrate hydrate is excellent in stability.

The substituents of the onium compound as the component (A) may be the same or different. In view of excellent stability of the semiclathrate hydrate, it is preferred that at least some of the substituents of the onium compound as the component (A) be the same, and it is more preferred that all of the four substituents be the same.

Examples of the component (A) satisfying the above preferred conditions include quaternary ammonium halides such as tetrabutylammonium hydroxide (melting point when made into an aqueous solution having a concentration of 1 mol/L: 26° C.) and tetrabutylammonium bromide (melting point when made into an aqueous solution having a concentration of 1 mol/L: 15° C.), and phosphonium salt compounds such as tetrabutylphosphonium hydroxide (melting point when made into an aqueous solution having a concentration of 1 mol/L: 17° C.).

One of these components (A) may be used alone, or two or more thereof may be used in combination. Among these components (A), tetrabutylammonium hydroxide, tetrabutylphosphonium hydroxide, and tetrabutylammonium bromide are preferable; tetrabutylammonium hydroxide and tetrabutylammonium bromide are more preferable; and tetrabutylammonium hydroxide is still more preferable, because the semiclathrate hydrate is excellent in stability.

The etching composition (2) of the present disclosure contains a quaternary ammonium halide among the components (A) of the etching composition (1) of the present disclosure, and the quaternary ammonium halide is preferably tetrabutylammonium hydroxide or tetrabutylammonium bromide, and more preferably tetrabutylammonium hydroxide, because the semiclathrate hydrate is excellent in stability.

One of these quaternary ammonium halides may be used alone, or two or more thereof may be used in combination.

The etching composition (3) of the present disclosure contains a phosphonium salt compound among the components (A) of the etching composition (1) of the present disclosure, and the phosphonium salt compound is preferably tetrabutylphosphonium hydroxide because the semiclathrate hydrate is excellent in stability.

One of these phosphonium salt compounds may be used alone, or two or more thereof may be used in combination.

A concentration of the component (A) in the etching composition (1) of the present disclosure is preferably from 0.01 mol/L to 3 mol/L, more preferably from 0.02 mol/L to 2 mol/L, and still more preferably from 0.03 mol/L to 1.5 mol/L. When the concentration of the component (A) is 0.01 mol/L or more, the selective solubility of silicon relative to silicon germanium is excellent. When the concentration of the component (A) is 3 mol/L or less, the etch rate of silicon is excellent.

Similarly, a concentration of the quaternary ammonium halide in the etching composition (2) of the present disclosure is preferably from 0.01 mol/L to 3 mol/L, more preferably from 0.02 mol/L to 2 mol/L, and still more preferably from 0.03 mol/L to 0.2 mol/L. When the concentration of the quaternary ammonium halide is 0.01 mol/L or more, the selective solubility of silicon relative to silicon germanium is excellent. In addition, when the concentration of the quaternary ammonium halide is 3 mol/L or less, the etch rate of silicon is excellent.

Similarly, a concentration of the phosphonium salt compound in the etching composition (3) of the present disclosure is preferably from 0.01 mol/L to 3 mol/L, more preferably from 0.02 mol/L to 2 mol/L, and still more preferably from 0.03 mol/L to 1.5 mol/L. When the concentration of the phosphonium salt compound is 0.01 mol/L or more, the selective solubility of silicon relative to silicon germanium is excellent. When the concentration of the phosphonium salt compound is 3 mol/L or less, the etch rate of silicon is excellent.

### (Component (B))

The etching composition of the present disclosure preferably further contains a basic compound (B) (hereinafter, sometimes referred to as “component (B)”), in addition to the component (A) (including a quaternary ammonium halide or a phosphonium salt compound; the same applies hereinafter), because the etch rate of silicon is excellent. In particular, when the component (A) alone does not provide basicity, the component (B) is preferably contained.

In the present disclosure, the “basic compound” refers to a compound that, when dissolved in water, gives an aqueous solution having a higher pH than that before the dissolution.

The component (B) does not include a compound corresponding to the component (A).

Examples of the component (B) include tetramethylammonium hydroxide, ethyltrimethylammonium hydroxide, butyltrimethylammonium hydroxide, tetraethylammonium hydroxide, tetrapropylammonium hydroxide, benzyltrimethylammonium hydroxide, sodium hydroxide, potassium hydroxide, and choline.

One of these components (B) may be used alone, or two or more thereof may be used in combination.

Among these components (B), quaternary ammonium hydroxides having an alkyl group with 3 or less carbon atoms, such as tetramethylammonium hydroxide, tetraethylammonium hydroxide, and tetrapropylammonium hydroxide, are preferable; tetramethylammonium hydroxide and tetraethylammonium hydroxide are more preferable; and tetramethylammonium hydroxide is still more preferable, because the etch rate of silicon is excellent.

A concentration of the component (B) in the etching composition of the present disclosure is preferably from 0.01 mol/L to 3 mol/L, more preferably from 0.05 mol/L to 2.5 mol/L, and still more preferably from 0.1 mol/L to 2 mol/L. When the concentration of the component (B) is 0.01 mol/L or more, the etch rate of silicon is excellent. When the concentration of the component (B) is 3 mol/L or less, the selective solubility of silicon relative to silicon germanium is excellent.

### (Solvent)

The etching composition of the present disclosure preferably further contains water in addition to the component (A) and the component (B), because the etch rate of silicon is excellent.

A content rate of water in the etching composition of the present disclosure is preferably from 5 mass % to 99 mass %, more preferably from 10 mass % to 95 mass %, and still more preferably from 50 mass % to 90 mass %. When the content rate of water is 5 mass % or more, the dissolution of silicon is promoted, and the selective solubility of silicon relative to silicon germanium is excellent. When the content rate of water is 99 mass % or less, the dissolution of silicon germanium is suppressed, and the selective solubility of silicon relative to silicon germanium is excellent.

### (Water-Miscible Solvent)

The etching composition of the present disclosure may further contain a water-miscible solvent in addition to the component (A), the component (B) and water.

The water-miscible solvent may be any solvent as long as it has excellent solubility in water, and a solvent having a solubility parameter (SP value) of 7.0 or more is preferable, and a solvent having a solubility parameter (SP value) of 9.0 or more is more preferable.

Examples of the water-miscible solvent include polar protic solvents such as isopropanol, ethylene glycol, propylene glycol, methanol, ethanol, propanol, butanol, glycerol, and 2-(2-aminoethoxyethanol); and polar aprotic solvents such as acetone, dimethyl sulfoxide, N,N-dimethyl formamide, N-methyl pyrrolidone, and acetonitrile.

One of these water-miscible solvents may be used alone, or two or more thereof may be used in combination.

A content rate of the water-miscible solvent in the etching composition of the present disclosure is preferably 20 mass % or less, more preferably 10 mass % or less, and still more preferably 0 mass %, per 100 mass % of the etching composition, because the dissolution of silicon is promoted and the selective solubility of silicon relative to silicon germanium is excellent.

### (Additional Component)

The etching composition of the present disclosure may contain an additional component other than the above components within a range where the effects of the present disclosure are not impaired.

Examples of the additional component include a chelating agent and a surfactant.

### (Composition)

In a case where the etching composition of the present disclosure contains the component (B), a molar ratio of the component (B) to the component (A) in the etching composition (molar concentration of component (B)/molar concentration of component (A)) is preferably from 0.01 to 1000, more preferably from 0.1 to 100, and still more preferably from 0.5 to 20. When the molar ratio of the component (B) to the component (A) in the etching composition of the present disclosure is 0.01 or more, the etch rate is excellent. In addition, when the molar ratio of the component (B) to the component (A) in the etching composition of the present disclosure is 1000 or less, the selective solubility of silicon relative to silicon germanium is excellent.

A pH of the etching composition of the present disclosure is preferably from 8 to 14, more preferably from 9 to 14, and still more preferably from 10 to 14, because the etch rate of silicon is excellent.

### (Oxygen Concentration)

The etching composition of the present disclosure has an oxygen concentration of 2 ppm by mass or less, preferably has an oxygen concentration of 1 ppm by mass or less, and more preferably has an oxygen concentration of 0.5 ppm by mass or less, because the selective solubility of silicon relative to silicon germanium is excellent.

A lower limit of the oxygen concentration of the etching composition of the present disclosure is not particularly limited, but is usually 0.01 ppm by mass or more from the viewpoint of use in the atmosphere.

In particular, in the etching composition of the etching composition (1) of the present disclosure, a mass ratio of oxygen to the component (A) in the etching composition is set to from 1×10⁻⁸ to 1×10⁻⁴. When the mass ratio is less than 1×10⁻⁸, it may be difficult to maintain the dissolved oxygen concentration in this range in the atmosphere, and extra cost is required for the maintenance, and when the mass ratio exceeds 1×10⁻⁴, it may be difficult to obtain the selective solubility of silicon relative to silicon germanium.

The mass ratio of oxygen to the component (A) in the etching composition is particularly preferably from 1×10⁻⁸ to 5×10⁻⁵, more preferably from 2×10⁻⁸ to 5×10⁻⁶, and particularly preferably from 5×10⁻⁸ to 1×10⁻⁶.

### (Etching Performance)

An etch rate ER_{Si} of silicon of the etching composition of the present disclosure in a structure in which silicon germanium having a film thickness of 10 nm and silicon having a film thickness of 10 nm are stacked is preferably 7 nm/min or more, and more preferably 10 nm/min or more, because the selective solubility of silicon relative to silicon germanium is excellent.

An etch rate ER_{SiGe} of silicon germanium of the etching composition of the present disclosure in a structure in which silicon germanium having a film thickness of 10 nm and silicon having a film thickness of 10 nm are stacked is preferably 6.5 nm/min or less, and more preferably 5 nm/min or less, because the selective solubility of silicon relative to silicon germanium is excellent.

A dissolution selectivity ratio of silicon to silicon germanium (ER_{Si}/ER_{SiGe}) of the etching composition of the present disclosure in a structure in which silicon germanium having a film thickness of 10 nm and silicon having a film thickness of 10 nm are stacked is preferably 1.50 or more, and more preferably 1.60 or more, because the selective solubility of silicon relative to silicon germanium is excellent.

The etch rate ER_{Si}, the etch rate ER_{SiGe}, and the dissolution selectivity ratio are measured and calculated by methods described in the examples described later.

### (Target for Etching)

The etching composition of the present disclosure can suppress dissolution of silicon germanium, promote dissolution of silicon, have excellent selective solubility of silicon relative to silicon germanium, and provide an excellent surface state of a substrate after etching. Therefore, the etching composition of the present disclosure is suitable for a structure containing silicon and silicon germanium, for example, a semiconductor device as a target for etching, and is particularly suitable for a structure in which silicon and silicon germanium necessary for forming a GAA FET are alternately stacked.

The silicon as the target for etching is preferably single crystal silicon because single crystal silicon germanium has excellent characteristics of a gate-all-around transistor, and single crystal silicon germanium is less likely to have defects when epitaxially grown on single crystal silicon germanium.

A content rate of silicon in the silicon germanium as the target for etching is preferably from 10 mass % to 95 mass %, and more preferably from 20 mass % to 85 mass %, per 100 mass % of the silicon germanium, since the content rate is suitable for etching by the etching composition of the present disclosure.

A content rate of germanium in the silicon germanium as the target for etching is preferably from 5 mass % to 90 mass %, and more preferably from 15 mass % to 80 mass %, per 100 mass % of the silicon germanium, since the content rate is suitable for etching by the etching composition of the present disclosure.

An alloy film of silicon germanium may be manufactured through film formation by a known method, but is preferably manufactured through film formation by a crystal growth method because of excellent mobility of electrons and holes after formation of a transistor.

In the structure containing silicon and silicon germanium and the structure in which silicon and silicon germanium are alternately stacked, silicon oxide, silicon nitride, silicon carbonitride, or the like may be exposed.

### [Method for Manufacturing Etching Composition]

The method for manufacturing an etching composition of the present disclosure is not particularly limited, and an etching composition can be manufactured by mixing the component (A) and, as necessary, the component (B), the solvent, and the additional component.

The order of mixing is not particularly limited, and all the components may be mixed at once, or some components may be mixed in advance and then the remaining components may be mixed.

To produce an etching composition having an oxygen concentration of 2 ppm by mass or less, the method for manufacturing an etching composition of the present disclosure preferably includes bubbling a gas having an oxygen concentration of 8 vol % or less (the remainder is preferably a nitrogen gas), more preferably includes bubbling a gas having an oxygen concentration of 3 vol % or less (the remainder is preferably a nitrogen gas), still more preferably includes bubbling a gas having an oxygen concentration of 1 vol % or less (the remainder is preferably a nitrogen gas), and most preferably includes a step of bubbling a gas containing 100 vol % of a nitrogen gas, in a mixed liquid prepared by mixing the component (A) and, as necessary, the component (B), the solvent, and the additional component.

A bubbling time in the step of bubbling the gas having a low oxygen concentration is not particularly limited as long as an etching composition having an oxygen concentration of 2 ppm by mass or less can be produced, but is usually about 1 to 15 minutes.

A treatment temperature during bubbling is not particularly limited, and slight warming may be performed to increase removal efficiency of oxygen. Usually, by using the gas having a low oxygen concentration as described above, a sufficient oxygen removal effect can be obtained at normal temperature (room temperature) without performing special warming.

The bubbling step described above is preferably performed after mixing all the components of the etching composition and immediately before etching. To maintain the oxygen concentration, bubbling is preferably continued even during etching.

### [Etching Method]

The etching method of the present disclosure is a method of etching a structure containing silicon and silicon germanium using the etching composition of the present disclosure.

The silicon as the target for etching is preferably single crystal silicon because single crystal silicon germanium has excellent characteristics of a gate-all-around transistor, and single crystal silicon germanium is less likely to have defects when epitaxially grown on single crystal silicon germanium.

As an etching method, a known method can be used, and examples thereof include a batch type and a single-wafer type.

A temperature during etching is preferably 15° C. or higher, and more preferably 20° C. or higher, because the etch rate can be improved.

The temperature during etching is preferably 100° C. or lower, and more preferably 80° C. or lower, from the viewpoints of reduction of damage to a substrate and stability of etching.

The temperature during etching corresponds to the temperature of the etching composition during etching.

### [Application]

The etching composition of the present disclosure is suitable for an etching liquid, more suitable for an etching liquid that dissolves silicon, and particularly suitable for an etching liquid that suppresses dissolution of silicon germanium and dissolves silicon, because the etching composition can suppress dissolution of silicon germanium, promote dissolution of silicon, have excellent selective solubility of silicon relative to silicon germanium, and provide an excellent surface state of a substrate after etching.

The etching composition of the present disclosure and the etching method of the present disclosure can be suitably used in the manufacture of a semiconductor device including etching a structure containing silicon and silicon germanium, and can suppress dissolution of silicon germanium, promote dissolution of silicon, have excellent selective solubility of silicon relative to silicon germanium, and provide an excellent surface state of a substrate after etching.

Therefore, the etching composition of the present disclosure and the etching method of the present disclosure can be particularly suitably used in the manufacture of a GAA FET including etching a structure containing silicon and silicon germanium. In particular, they are suitable for a structure in which silicon and silicon germanium necessary for forming a GAA FET are alternately stacked.

### EXAMPLES

Hereinafter, the present disclosure will be more specifically described with reference to examples. The present disclosure is not limited to the following examples as long as it does not depart from the gist of the present disclosure.

### <Raw Material>

In the following Examples and Comparative Examples, the following materials were used as raw materials for manufacturing etching compositions.
(Component (A): Semiclathrate Hydrate-Forming Compound (A))
Component (A-1): tetrabutylammonium hydroxide
Component (A-2): tetrabutylphosphonium hydroxide
Component (A-3): tetrabutylammonium bromide
(Component (B): Basic Compound (B))
Component (B-1): tetraethylammonium hydroxide
Component (B-2): potassium hydroxide
Component (B-3): tetramethylammonium hydroxide
Component (B-4): tetrapropylammonium hydroxide
Component (B-5): butyltrimethylammonium hydroxide
Component (B-6): choline

Table 1 shows the presence or absence of a melting point of 5° C. or higher when each of the above components was made into an aqueous solution having a concentration of 1 mol/L, and the melting point. The melting point was measured by a differential scanning calorimeter DSC7020 available from Hitachi High-Tech Science Corporation. The aqueous solution was placed in a sample pan for thermal analysis made of SUS and sealed, and the temperature was changed in the order of normal temperature→60° C. (temperature rising rate: 20° C./min), 60° C.→−70° C. (temperature falling rate: 10° C./min), and −70° C.→60° C. (temperature rising rate: 10° C./min). An endothermic peak appearing around 0° C. during the temperature change of −70° C.→60° C. (temperature rising rate: 10° C./min) was determined to be a melting point derived from water, and peak top temperatures of endothermic peaks appearing at temperatures other than this were determined to be melting points derived from the compounds.

TABLE 1

| | Presence or absence of melting point | |
|---|---|---|
| | of 5° C. or higher when the component | Melting point |
| Type of | was made into aqueous solution with | indicated in |
| component | concentration of 1 mol/L | left column |
| (A-1) | Present | 26° C. |
| (A-2) | Present | 17° C. |
| (A-3) | Present | 15° C. |
| (B-1) | Absent | — |
| (B-2) | Absent | — |
| (B-3) | Absent | — |
| (B-4) | Absent | — |
| (B-5) | Absent | — |
| (B-6) | Absent | — |

### <Evaluation of Etching Composition>

### (Measurement of Oxygen Concentration)

A polarographic dissolved oxygen concentration meter (model name “HI 2004-01,” available from HANNA) and a probe of a fluorescent dissolved oxygen concentration meter (available from HAMILTON) were immersed in the etching composition produced in each of the Examples and Comparative Examples under stirring, and the oxygen concentration [ppm by mass] in the etching composition was measured.

### (Etch Rate of Silicon)

A substrate including a structure in which silicon germanium having a film thickness of 10 nm and silicon having a film thickness of 10 nm were stacked was immersed in a 0.5 mass % hydrofluoric acid aqueous solution for 60 seconds, then rinsed with ultrapure water, dried, and stored in a nitrogen atmosphere. Thereafter, the substrate was immersed in the etching composition produced in each of the Examples and Comparative Examples at a temperature as shown in Table 3 for a time as shown in Table 3, and then rinsed with ultrapure water and dried. The cross section of the substrate after immersion was observed with an electron microscope, the width [nm] of a silicon layer was measured, and the etch rate ER_{Si} [nm/min] of silicon was calculated using the following equation (1).

$${ER}_{Si} [ nm / min ] = ( width of silicon layer before immersion - width of silicon layer after immersion ) \div immersion time [ m in ] \qquad ( 1 )$$

### (Etch Rate of Silicon Germanium)

A substrate including a structure in which silicon germanium having a film thickness of 10 nm and silicon having a film thickness of 10 nm were stacked was immersed in a 0.5 mass % hydrofluoric acid aqueous solution for 60 seconds, then rinsed with ultrapure water, dried, and stored in a nitrogen atmosphere. Thereafter, the substrate was immersed in the etching composition produced in each of the Examples and Comparative Examples at a temperature as shown in Table 3 for a time as shown in Table 3, and then rinsed with ultrapure water and dried. The cross section of the substrate after immersion was observed with an electron microscope, the width [nm] of a silicon germanium layer was measured, and the etch rate ER_{SiGe} [nm/min] of the silicon germanium layer was calculated using the following equation (2).

$${ER}_{SiGe} [ nm / min ] = ( width of silicon germanium layer before immersion - width of silicon germanium layer after immersion ) \div immersion time [ m in ] \qquad ( 2 )$$

### (Dissolution Selectivity Ratio of Silicon to Silicon Germanium)

The dissolution selectivity ratio of silicon to silicon germanium was calculated using the following equation (3).

$$Dissolution selectivity ratio = {ER}_{Si} [ nm / min ] \div {ER}_{SiGe} [ nm / min ] \qquad ( 3 )$$

### (Substrate Surface State)

A substrate including a structure in which silicon germanium having a film thickness of 10 nm and silicon having a film thickness of 10 nm were stacked was immersed in a 0.5 mass % hydrofluoric acid aqueous solution for 60 seconds, then rinsed with ultrapure water, dried, and stored in a nitrogen atmosphere. Thereafter, the substrate was immersed in the etching composition produced in each of the Examples and Comparative Examples at a temperature as shown in Table 3 for a time as shown in Table 3, and then rinsed with ultrapure water and dried. The cross section of the substrate after immersion was observed with an electron microscope, and the substrate surface was evaluated according to the following criteria.
A: The substrate surface was uniform and smooth.
B: The substrate surface was uneven or unsmooth.

### Example 1

The component (A-1) was dissolved in water as a solvent so that the concentration of the component (A-1) was 1 mol/L, and the resulting solution was bubbled with a nitrogen gas having an oxygen concentration of 0 vol % for 10 minutes to produce an etching composition having an oxygen concentration as shown in Table 2A.

The mass ratio of oxygen to the component (A-1) of the etching composition was 0.40×10⁻⁶/0.259=1.5×10⁻⁶.

The pH of the etching composition was 14 as measured by a pH electrode 9632-10D for a strong alkaline sample available from HORIBA (using a portable pH meter D-74 available from HORIBA).

The etching conditions and evaluation results of the resulting etching composition are shown in Table 3A.

### Examples 2 to 18

Etching compositions having oxygen concentrations and pHs as shown in Table 2A were obtained by the same operation as in Example 1 except that the type and concentration of the component (A), the type and concentration of the component (B), and the oxygen concentration in the nitrogen gas with which the solution was bubbled were changed as shown in Table 2A.

The etching conditions and evaluation results of the resulting etching compositions are shown in Table 3A.

### Example 19

An etching composition having an oxygen concentration and a pH as shown in Table 2A was produced by the same operation as in Example 16 except that a mixed solvent containing 90 mass % of water and 10 mass % of isopropyl alcohol was used.

The etching conditions and evaluation results of the resulting etching composition are shown in Table 3A.

### Comparative Examples 1 to 17

Etching compositions having oxygen concentrations and pHs as shown in Table 2B were produced by the same operation as in Example 1 except that the type and concentration of the component (A), the type and concentration of the component (B), and the oxygen concentration in the nitrogen gas with which the solution was bubbled were changed as shown in Table 2B.

The etching conditions and evaluation results of the resulting etching compositions are shown in Table 3B.

In the following Tables 3A and 3B, the mass ratio of oxygen to the compound (A) of the etching composition is denoted as “O₂/component (A).”

TABLE 2A

| | | | | | | Oxygen | |
|---|---|---|---|---|---|---|---|
| | | | | | Oxygen | concentration | |
| | Component (A) | | Component (B) | | concentration | in etching | pH of |
| | | Concentration | | Concentration | in bubbling gas | composition | etching |
| | Type | [mol/L] | Type | [mol/L] | [vol %] | [ppm by mass] | composition |
| Example 1 | (A-1) | 1 | — | — | 0 | 0.40 | 14 |
| Example 2 | (A-1) | 1 | — | — | 2 | 0.74 | 14 |
| Example 3 | (A-1) | 1 | — | — | 5 | 1.48 | 14 |
| Example 4 | (A-1) | 0.5 | — | — | 0 | 0.21 | 14 |
| Example 5 | (A-2) | 1 | — | — | 0 | 0.18 | 14 |
| Example 6 | (A-2) | 1 | — | — | 2 | 0.55 | 14 |
| Example 7 | (A-2) | 1 | — | — | 5 | 1.26 | 14 |
| Example 8 | (A-1) | 0.5 | (B-1) | 0.5 | 0 | 0.28 | 14 |
| Example 9 | (A-1) | 0.5 | (B-1) | 0.5 | 2 | 0.59 | 14 |
| Example 10 | (A-1) | 0.5 | (B-1) | 0.5 | 5 | 1.28 | 14 |
| Example 11 | (A-1) | 0.1 | (B-2) | 0.9 | 0 | 0.18 | 14 |
| Example 12 | (A-3) | 0.1 | (B-2) | 1 | 0 | 0.59 | 14 |
| Example 13 | (A-3) | 0.1 | (B-3) | 0.22 | 0 | 0.45 | 13 |
| Example 14 | (A-3) | 0.1 | (B-1) | 1 | 0 | 0.29 | 14 |
| Example 15 | (A-3) | 0.1 | (B-4) | 1 | 0 | 0.10 | 14 |
| Example 16 | (A-3) | 0.1 | (B-5) | 1 | 0 | 0.19 | 14 |
| Example 17 | (A-3) | 0.1 | (B-6) | 0.25 | 0 | 0.07 | 13 |
| Example 18 | (A-1) | 0.5 | — | — | 0 | 0.21 | 14 |
| | (A-3) | 0.5 | | | | | |
| Example 19 | (A-1) | 0.5 | — | — | 0 | 0.29 | 14 |
| | (A-3) | 0.5 | | | | | |

TABLE 2B

| | | | | | | Oxygen | |
|---|---|---|---|---|---|---|---|
| | | | | | Oxygen | concentration | |
| | Component (A) | | Component (B) | | concentration | in etching | pH of |
| | | Concentration | | Concentration | in bubbling | composition | etching |
| | Type | [mol/L] | Type | [mol/L] | gas [vol %] | [ppm by mass] | composition |
| Comparative | (A-1) | 1 | — | — | 10 | 2.88 | 14 |
| Example 1 | | | | | | | |
| Comparative | (A-1) | 1 | — | — | 21 | 5.54 | 14 |
| Example 2 | | | | | | | |
| Comparative | (A-2) | 1 | — | — | 21 | 3.84 | 14 |
| Example 3 | | | | | | | |
| Comparative | (A-1) | 0.5 | (B-1) | 0.5 | 21 | 4.60 | 14 |
| Example 4 | | | | | | | |
| Comparative | — | — | (B-3) | 1 | 0 | 0.11 | 14 |
| Example 5 | | | | | | | |
| Comparative | — | — | (B-3) | 1 | 2 | 0.47 | 14 |
| Example 6 | | | | | | | |
| Comparative | — | — | (B-3) | 1 | 5 | 1.00 | 14 |
| Example 7 | | | | | | | |
| Comparative | — | — | (B-3) | 1 | 21 | 4.38 | 14 |
| Example 8 | | | | | | | |
| Comparative | — | — | (B-3) | 0.22 | 0 | 0.42 | 13 |
| Example 9 | | | | | | | |
| Comparative | — | — | (B-3) | 0.22 | 2 | 0.24 | 13 |
| Example 10 | | | | | | | |
| Comparative | — | — | (B-3) | 0.22 | 5 | 1.70 | 13 |
| Example 11 | | | | | | | |
| Comparative | — | — | (B-3) | 0.22 | 21 | 5.52 | 13 |
| Example 12 | | | | | | | |
| Comparative | — | — | (B-2) | 1 | 0 | 0.36 | 14 |
| Example 13 | | | | | | | |
| Comparative | — | — | (B-1) | 1 | 0 | 0.74 | 14 |
| Example 14 | | | | | | | |
| Comparative | — | — | (B-4) | 1 | 0 | 0.68 | 14 |
| Example 15 | | | | | | | |
| Comparative | — | — | (B-5) | 1 | 0 | 0.77 | 14 |
| Example 16 | | | | | | | |
| Comparative | — | — | (B-6) | 0.25 | 0 | 0.54 | 13 |
| Example 17 | | | | | | | |

TABLE 3A

| | Etching conditions | | | | Dissolution | Substrate | |
|---|---|---|---|---|---|---|---|
| | Temperature | Time | ERₛᵢ | ER_{SiGe} | selectivity | surface | O₂/component |
| | [° C.] | [min] | [nm/min] | [nm/min] | ratio | state | (A) |
| Example 1 | 50 | 7 | 3.1 | 0.4 | 7.75 | A | 1.54 × 10⁻⁶ |
| Example 2 | 50 | 7 | 3.4 | 0.7 | 4.86 | A | 2.85 × 10⁻⁶ |
| Example 3 | 50 | 7 | 3.6 | 2 | 1.80 | A | 5.70 × 10⁻⁶ |
| Example 4 | 50 | 5 | 3.7 | 0.2 | 18.50 | A | 1.62 × 10⁻⁶ |
| Example 5 | 50 | 7 | 3.7 | 0.7 | 5.29 | A | 6.51 × 10⁻⁷ |
| Example 6 | 50 | 7 | 4 | 1.1 | 3.64 | A | 1.99 × 10⁻⁶ |
| Example 7 | 50 | 7 | 3.7 | 1.9 | 1.95 | A | 4.56 × 10⁻⁶ |
| Example 8 | 50 | 5 | 5.6 | 0.9 | 6.22 | A | 2.16 × 10⁻⁶ |
| Example 9 | 50 | 5 | 5.8 | 1.2 | 4.83 | A | 4.55 × 10⁻⁶ |
| Example 10 | 50 | 5 | 6.8 | 2.2 | 3.09 | A | 9.87 × 10⁻⁶ |
| Example 11 | 50 | 7 | 3.7 | 0.7 | 5.29 | A | 6.94 × 10⁻⁶ |
| Example 12 | 50 | 5 | 4 | 1.1 | 3.64 | A | 1.83 × 10⁻⁵ |
| Example 13 | 50 | 5 | 3.7 | 1.9 | 1.95 | A | 1.40 × 10⁻⁵ |
| Example 14 | 50 | 5 | 2.8 | 0.5 | 5.60 | A | 9.00 × 10⁻⁶ |
| Example 15 | 50 | 7 | 6.3 | 2.4 | 2.63 | A | 3.10 × 10⁻⁶ |
| Example 16 | 50 | 7 | 2.1 | 0.8 | 2.63 | A | 5.89 × 10⁻⁶ |
| Example 17 | 50 | 7 | 4.7 | 1.1 | 4.27 | A | 2.17 × 10⁻⁶ |
| Example 18 | 50 | 5 | 3.5 | 0.5 | 7.00 | A | 7.22 × 10⁻⁷ |
| Example 19 | 50 | 5 | 2.5 | 0.3 | 8.33 | A | 9.97 × 10⁻⁷ |

TABLE 3B

| | Etching conditions | | | | Dissolution | Substrate | |
|---|---|---|---|---|---|---|---|
| | Temperature | Time | ER_{Si} | ER_{SiGe} | selectivity | surface | O₂/component |
| | [° C.] | [min] | [nm/min] | [nm/min] | ratio | state | (A) |
| Comparative | 50 | 7 | 3.2 | 2.3 | 1.39 | A | 1.11 × 10⁻⁵ |
| Example 1 | | | | | | | |
| Comparative | 50 | 7 | 2.9 | 2.2 | 1.32 | A | 2.14 × 10⁻⁵ |
| Example 2 | | | | | | | |
| Comparative | 50 | 7 | 2.5 | 1.9 | 1.32 | A | 1.39 × 10⁻⁵ |
| Example 3 | | | | | | | |
| Comparative | 50 | 5 | 6.4 | 5.4 | 1.19 | A | 3.55 × 10⁻⁵ |
| Example 4 | | | | | | | |
| Comparative | 50 | 7 | 5.4 | 4.9 | 1.10 | B | — |
| Example 5 | | | | | | | |
| Comparative | 50 | 7 | 7 | 6.5 | 1.08 | B | — |
| Example 6 | | | | | | | |
| Comparative | 50 | 7 | 7.4 | 6.8 | 1.09 | B | — |
| Example 7 | | | | | | | |
| Comparative | 50 | 7 | 11.4 | 10.6 | 1.08 | B | — |
| Example 8 | | | | | | | |
| Comparative | 50 | 7 | 3.7 | 3.6 | 1.03 | B | — |
| Example 9 | | | | | | | |
| Comparative | 50 | 7 | 4.8 | 4.5 | 1.07 | B | — |
| Example 10 | | | | | | | |
| Comparative | 50 | 7 | 14.5 | 14.2 | 1.02 | B | — |
| Example 11 | | | | | | | |
| Comparative | 50 | 7 | 8.5 | 7.8 | 1.09 | B | — |
| Example 12 | | | | | | | |
| Comparative | 50 | 5 | 5.2 | 4.8 | 1.08 | B | — |
| Example 13 | | | | | | | |
| Comparative | 50 | 7 | 5.3 | 4.1 | 1.29 | B | — |
| Example 14 | | | | | | | |
| Comparative | 50 | 7 | 7.6 | 4.5 | 1.69 | B | — |
| Example 15 | | | | | | | |
| Comparative | 50 | 7 | 3.8 | 2.9 | 1.31 | B | — |
| Example 16 | | | | | | | |
| Comparative | 50 | 5 | 6.6 | 5.8 | 1.14 | B | — |
| Example 17 | | | | | | | |

As can be seen from Tables 3A and 3B, the etching compositions produced in Examples can suppress dissolution of silicon germanium, promote dissolution of silicon, have excellent selective solubility of silicon relative to silicon germanium, and provide an excellent surface state of a substrate after etching. On the other hand, the etching compositions produced in Comparative Examples were inferior in at least one of the selective solubility of silicon relative to silicon germanium or the substrate surface state and could not achieve both of them.

### INDUSTRIAL APPLICABILITY

The etching composition of the present disclosure and the etching method of the present disclosure using the etching composition can suppress dissolution of silicon germanium, promote dissolution of silicon, have excellent selective solubility of silicon relative to silicon germanium, and provide an excellent surface state of a substrate after etching. Therefore, the etching composition of the present disclosure and the etching method of the present disclosure using the etching composition are suitable for a structure containing silicon and silicon germanium as a target for etching. For example, the etching composition and etching method of the present disclosure can be suitably used in the manufacture of a semiconductor device and can be particularly suitably used in the manufacture of a GAA FET, including etching a structure containing silicon and silicon germanium.

Although the present disclosure has been described in detail with reference to specific embodiments, it will be apparent to those skilled in the art that various modifications can be made within the scope where the effects of the present disclosure are achieved.

The present application is based on Japanese Patent Application No. 2023-040024, filed on Mar. 14, 2023, which is incorporated by citation in its entirety.

1. An etching composition comprising a semiclathrate hydrate-forming compound (A), wherein
the semiclathrate hydrate-forming compound (A) comprises a compound having a melting point of 5° C. or higher when the semiclathrate hydrate-forming compound (A) is made into an aqueous solution having a concentration of 1 mol/L, and
the etching composition has an oxygen concentration of 2 ppm by mass or less, and a mass ratio of oxygen to the semiclathrate hydrate-forming compound (A) of from 1×10⁻⁸ to 1×10⁻⁴.

2. The etching composition according to claim 1, wherein the semiclathrate hydrate-forming compound (A) comprises an onium compound.

3. The etching composition according to claim 2, wherein the semiclathrate hydrate-forming compound (A) comprises at least one selected from the group consisting of an ammonium salt compound and a phosphonium salt compound.

4. The etching composition according to claim 1, wherein the semiclathrate hydrate-forming compound (A) comprises a compound having 10 or more carbon atoms.

5. The etching composition according to claim 2, wherein the semiclathrate hydrate-forming compound (A) comprises an onium compound having four identical substituents.

6. The etching composition according to claim 1, wherein a concentration of the semiclathrate hydrate-forming compound (A) in the etching composition is from 0.01 mol/L to 3 mol/L.

7. An etching composition comprising a quaternary ammonium halide,
wherein the etching composition has an oxygen concentration of 2 ppm by mass or less.

8. An etching composition comprising a phosphonium salt compound,
wherein the etching composition has an oxygen concentration of 2 ppm by mass or less.

9. The etching composition according to claim 1, further comprising a basic compound (B).

10. The etching composition according to claim 9, wherein a concentration of the basic compound (B) in the etching composition is from 0.01 mol/L to 3 mol/L.

11. The etching composition according to claim 1, further comprising water.

12. The etching composition according to claim 1, wherein the etching composition has a pH of from 8 to 14.

13. The etching composition according to claim 1, wherein the etching composition selectively dissolves silicon relative to silicon germanium.

14. A method for manufacturing the etching composition according to claim 1, the method comprising bubbling a gas having an oxygen concentration of 8 vol % or less in the etching composition including the semiclathrate hydrate-forming compound (A).

15. An etching method comprising etching a structure containing silicon and silicon germanium using the etching composition according to claim 1.

16. A method for manufacturing a semiconductor device, the method comprising etching a structure containing silicon and silicon germanium using the etching composition according to claim 1.

17. A method for manufacturing a gate-all-around transistor, the method comprising etching a structure containing silicon and silicon germanium using the etching composition according to claim 1.
